(19) United States
(12) Patent Application Publication
(10) Pub. No.: US 2007/0205696 A1
(43) Pub. Date: Sep. 6, 2007

(54) Vibroswitch for flickering shoes

(75) Inventor: Deen Chen, Nanan (CN)

Correspondence Address: CHARLES E. BAXLEY, ESQ., 90 JOHN STREET, THIRD FLOOR, NEW YORK, NY, 10038, US

(73) Assignee: Putian Newpower International Trade Co., Ltd.

(21) Appl. No.: 11/370,272

(22) Filed: Mar. 6, 2006

(51) Int. Cl. H01L 41/00

(52) U.S. Cl. 310/324

(57) ABSTRACT

The present invention provides a vibro-switch for flickering shoes, which typically includes a plastic shell comprising of a hood and a hood pad enclosing a cylindrical cavity; disk cooper sheet attached with a piezoelectric ceramics chip on the bottom side is suspended in the cylindrical cavity of said closed hood and hood pad so that the both sides of the stuck cooper sheet and the piezoelectric ceramics chip are kept certain space to the shell; a metal ball is put on top surface of the cooper sheet so as to roll freely; two cords, among of them, one is connected to the cooper sheet from the bottom side and led out the shell, the another is connected to the piezoelectric ceramics chip from the bottom side and stretched out of the shell. The present invent provides a vibro-switch for flickering shoes having simple structure, high reliability, easy manufacturing with lower production cost features.

### BACKGROUND OF THE INVENTION

1. Field of the Invention

The present invention relates to a flickering shoes, and more particularly to a vibro-switch applied on the flickering shoes.

2. Description of Prior Art

In accordance with the conventional technology, the vibro-switches applied on the flickering shoes are divided into three kinds: one is to take mercury as a trigger electrode, but due to the environment protection sake, it can not be applied in practice; the next is to take a metal ball as a trigger electrode, due to the poor sensitivity, the applying effect of it is not as good as expected; the another is referred to the Chinese patent No.: 200320130395.4 discovered a vibro-switch taking a metal spring as conduction, wherein taking advantage of the swing of the spring, as shaking generated, the trigger electrode is cut on, so the vibro-switch is with high sensitivity, but the manufacturing process is more complex.

### OBJECTS AND SUMMARY OF THE INVENTION

It is therefore a main object of the present invention to provide a vibro-switch for flickering shoes having simple structure, high reliability, easy manufacturing with lower production cost.

For achieving the above-mentioned object, the present invention provides the technology as follows: a vibro-switch for flickering shoes, which typically includes a plastic shell having a hollow cavity;

A cooper sheet attached with a piezoelectric ceramics chip on the bottom side is suspended in said closed shell so that the both sides of the stuck cooper sheet and the piezoelectric ceramics chip are kept certain space to the shell;

A metal ball is put on top surface of the cooper sheet so as to roll freely;

Two cords, among of them, one is connected to the cooper sheet from the bottom side and led out the shell, the another is connected to the piezoelectric ceramics chip from the bottom side and stretched out of the shell.

A vibro-switch for flickering shoes, which typically includes a plastic shell comprising of a hood and a hood pad enclosing a hollow cavity;

A cooper sheet attached with a piezoelectric ceramics chip on the bottom side is suspended in said closed shell so that the both sides of the stuck cooper sheet and the piezoelectric ceramics chip are kept certain space to the shell;

A metal ball is put on top surface of the cooper sheet so as to roll freely;

Two cords, among of them, one is connected to the cooper sheet from the bottom side and led out the shell, the another is connected to the piezoelectric ceramics chip from the bottom side and stretched out of the shell.

A vibro-switch for flickering shoes, which typically includes a plastic shell comprising of a hood and a hood pad enclosing a cylindrical cavity;

A disk cooper sheet attached with a piezoelectric ceramics chip on the bottom side is suspended in the cylindrical cavity of said closed hood and hood pad so that the both sides of the stuck cooper sheet and the piezoelectric ceramics chip are kept certain space to the shell;

A metal ball is put on top surface of the cooper sheet so as to roll freely;

Two cords, among of them, one is connected to the cooper sheet from the bottom side and led out the shell, the another is connected to the piezoelectric ceramics chip from the bottom side and stretched out of the shell.

Said plastic insulating shell is appeared to cylinder, the piezoelectric ceramics chip and the cooper sheet are appeared to disk both.

Said piezoelectric ceramics chip is stuck on the center of the disk cooper sheet, and the rim of the disk cooper sheet is clamped by said hood and hood pad, and suspended in the cylindrical cavity.

Utilizing above-mentioned structure, the present invention takes piezoelectric ceramics chip as conductor of the vibro-switch, which is a kind of crystalline solid being used for picking up the change in shape or lengthen occurred by acoustic vibration whatever it is just so little generated by small mechanical pressure. Along with the shape change, the both sides of the crystalline solid will generate different electric charge, when sound wave exerts on the piezoelectric ceramics, said electric charge will be transferred into electric signals.

Therefore, in the present invention, when the shell is shaken, the small metal ball rolls over the cooper sheet in the hollow cavity of the shell to generate sound wave, the piezoelectric ceramics has the sound-electric transfer feature of the electric energy generated under the distortion state, thereby this feature, when the small metal ball rolls over the cooper sheet to generate sound wave to exert on said piezoelectric ceramics chip to distort the chip, the change in micro-shape of the piezoelectric ceramics chip will transfer into electric signals between the both sides of the chip, then electric signal output is led out from the cooper sheet and the bottom side of the piezoelectric ceramics chip to carry out switching function.

One word, the present invention has following advantages:

1. because the electric signal is created by the piezoelectric ceramics chip, without any mechanical contacting terminals, the service life of the product is efficiently postponed, and work is became more reliable;

2. the sensibility of sound-electric transfer of the piezoelectric ceramics chip is very high, so the metal ball can be manufactured into very small so that the whole volume of the goods can be decreased greatly;

3. Even if the metal ball is deserved into a cylindrical cavity, the shake coming from any direction can make the metal ball roll with high sensibility.

### BRIEF DESCRIPTION OF THE DRAWINGS

FIG. 1 is a perspective view of the present invention.

FIG. 2 is a sectional view showing the top view of the present invention.

FIG. 3 is a sectional side view of the present invention.

### DETAILED DESCRIPTION OF PREFERRED EMBODIMENTS

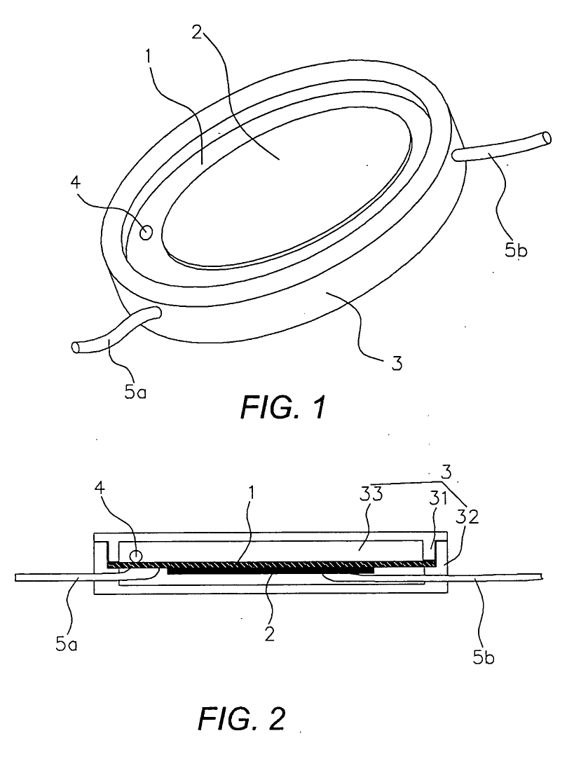

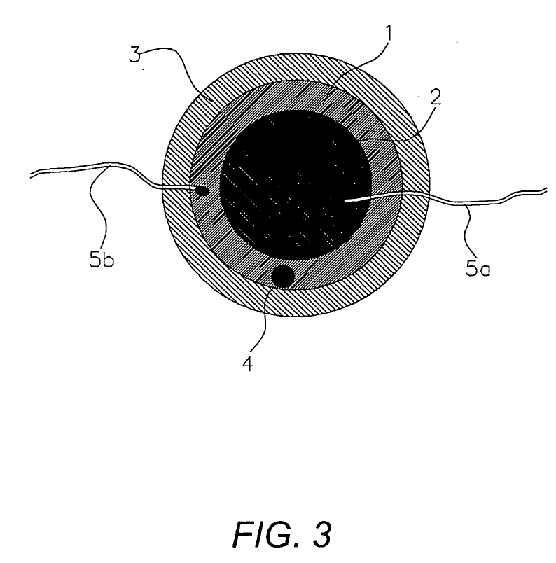

Referring to FIG. 1 and FIG. 2, a vibro-switch for flickering shoes discovered by the present invention typically includes a plastic shell 3 enclosing a cylindrical cavity. Wherein, in this embodiment, the plastic shell 3 is comprised of a circle hood 31 and matched hood pad 32, referring to FIG. 3, said hood 31 and the hood pad 32 surrounds a cylindrical cavity 33.

A disk cooper sheet 1 attached with a disk piezoelectric ceramics chip 2 at center of the bottom side is suspended over in the cylindrical cavity 33, wherein the disk cooper sheet 1 is bigger than the disk piezoelectric ceramics chip 2 in diameter, so that the rim of the disk cooper sheet 1 is clamped by the hood 31 and the hood pad 32 along the edge, there are gaps remained at the upward and downward of the stuck cooper sheet 1 and the piezoelectric ceramics chip 2 respectively, just like suspending in there.

A small metal ball 4 is reserved into the cylindrical cavity 33, such as laying over the top surface of the cooper sheet 1 clamped between the hood 31 and hood pad 32 rolling freely.

Two cords 5a 5b, among of them, one 5a is connected to the cooper sheet 1 from the bottom side and led out the shell 3, the another 5b is connected to the piezoelectric ceramics chip 2 from the bottom side and stretched out of the shell 3.

As using, when the shell 3 is shaken, the metal ball 4 rolls between the cooper sheet 1 and the inside cavity of the shell 3 to generate sound wave, the piezoelectric ceramics has the sound-electric transfer feature of the electric energy generated under the distortion state, thereby this feature, when the small metal ball 4 rolls over the cooper sheet 1 to generate sound wave to exert on said piezoelectric ceramics chip 2 to distort the chip, the change in micro-shape of the piezoelectric ceramics chip 2 will transfer into electric signals between the both sides of the chip 2, then electric signal output is led out from the cooper sheet 1 and the bottom side of the piezoelectric ceramics chip 2 to carry out switching function.

Certainly, the shape of the inside cavity 33 surrounded by the shell 3 is also not limited into said cylinder, in the same way, the shapes of the cooper sheet 1 and the piezoelectric ceramics chip are not limited into circle, except in the embodiment of the present invention, the cylindrical cavity 33 and the disk cooper sheet 1 and the disk piezoelectric ceramics chip 2 facilitate to the metal ball 4 to roll as the shake coming from any direction with high sensibility.

I claim:

1. A vibro-switch for flickering shoes typically including a plastic shell having a hollow cavity at inside; a cooper sheet attached with a piezoelectric ceramics chip on the bottom side is suspended in said closed shell so that the both sides of the stuck cooper sheet and the piezoelectric ceramics chip are kept certain space to the shell; a metal ball is put on top surface of the cooper sheet so as to roll freely; two cords, among of them, one is connected to the cooper sheet from the bottom side and led out the shell, the another is connected to the piezoelectric ceramics chip from the bottom side and stretched out of the shell.

2. A vibro-switch for flickering shoes typically including a plastic shell comprising of a hood and a hood pad enclosing a hollow cavity; a cooper sheet attached with a piezoelectric ceramics chip on the bottom side is suspended in said closed shell so that the both sides of the stuck cooper sheet and the piezoelectric ceramics chip are kept certain space to the shell; a metal ball is put on top surface of the cooper sheet so as to roll freely; two cords, among of them, one is connected to the cooper sheet from the bottom side and led out the shell, the another is connected to the piezoelectric ceramics chip from the bottom side and stretched out of the shell.

3. A vibro-switch for flickering shoes typically including a plastic shell comprising of a hood and a hood pad enclosing a cylindrical cavity; disk cooper sheet attached with a piezoelectric ceramics chip on the bottom side is suspended in the cylindrical cavity of said closed hood and hood pad so that the both sides of the stuck cooper sheet and the piezoelectric ceramics chip are kept certain space to the shell; a metal ball is put on top surface of the cooper sheet so as to roll freely; two cords, among of them, one is connected to the cooper sheet from the bottom side and led out the shell, the another is connected to the piezoelectric ceramics chip from the bottom side and stretched out of the shell.

4. A vibro-switch for flickering shoes as claimed in claim 1, wherein said plastic insulating shell is appeared to cylinder, the piezoelectric ceramics chip and the cooper sheet are appeared to disk both.

5. A vibro-switch for flickering shoes as claimed in claim 2, wherein said piezoelectric ceramics chip is stuck on the center of the disk cooper sheet, and the rim of the disk cooper sheet is clamped by said hood and hood pad, and suspended in the cylindrical cavity.

6. A vibro-switch for flickering shoes as claimed in claim 3, wherein said piezoelectric ceramics chip is stuck on the center of the disk cooper sheet, and the rim of the disk cooper sheet is clamped by said hood and hood pad, and suspended in the cylindrical cavity.

7. A vibro-switch for flickering shoes as claimed in claim 4, wherein said piezoelectric ceramics chip is stuck on the center of the disk cooper sheet, and the rim of the disk cooper sheet is clamped by said hood and hood pad, and suspended in the cylindrical cavity.
